(19) United States
(12) Patent Application Publication
(10) Pub. No.: US 2015/0037910 A1
(43) Pub. Date: Feb. 5, 2015

(54) METHOD OF MANUFACTURING ORGANIC ELECTROLUMINESCENT ELEMENT

(71) Applicants: Naoyuki Imai, Tokyo (JP); Kyousuke Masuya, Tokyo (JP); Masaru Tajima, Tokyo (JP)

(72) Inventors: Naoyuki Imai, Tokyo (JP); Kyousuke Masuya, Tokyo (JP); Masaru Tajima, Tokyo (JP)

(73) Assignee: SHOWA DENKO K.K., Minato-ku, Tokyo (JP)

(21) Appl. No.: 14/380,969

(22) PCT Filed: Feb. 28, 2013
(86) PCT No.: PCT/JP2013/055531

§ 371 Date: Aug. 26, 2014

(30) Foreign Application Priority Data
Feb. 29, 2012 (JP) 2012-044767

(51) Int. Cl. H01L 51/56

(52) U.S. Cl. CPC H01L 51/56
USPC 438/7

(57) ABSTRACT

A method of manufacturing an organic electroluminescent element including: a first manufacturing process of stacking at least a first electrode layer, a dielectric layer, and a second electrode layer on a substrate in this order, the organic electroluminescent element having a light-emitting portion that is in contact with an inner surface of a concave portion formed to penetrate the dielectric layer; measuring a brightness distribution of the organic electroluminescent element while causing the light-emitting portion to emit light by applying a voltage to the first electrode layer and the second electrode layer of the organic electroluminescent element manufactured in the first manufacturing process, and obtaining uneven brightness information of the organic electroluminescent element; and a second manufacturing process of adjusting concave portion density on the basis of the uneven brightness information obtained in the brightness distribution measurement process, and reducing uneven brightness of the organic electroluminescent element.

### TECHNICAL FIELD

The present invention relates to a method of manufacturing an organic electroluminescent element.

### BACKGROUND ART

In recent years, as a device utilizing electroluminescence, an organic electroluminescent element in which light-emitting materials composed of organic materials are formed as a layered state, and a pair of electrodes including an anode and a cathode is provided to the light-emitting layer, and light is emitted by applying a voltage thereto, becomes a focus of attention. For example, Patent Document 1 suggests a cavity-emission electroluminescent device that includes a dielectric layer interposed between a hole-injecting electrode layer and an electron-injecting electrode layer, and in which an electroluminescent coating material is applied to an interior cavity surface extending through at least the dielectric layer and one of the electrode layers and including a hole-injecting electrode region, an electron-injecting electrode region and a dielectric region.

### CITATION LIST

### Patent Literature

Patent Document 1: Japanese Patent Application Unexamined Publication (Translation of PCT Application) No. 2003-522371

### SUMMARY OF INVENTION

### Technical Problem

In the organic electroluminescent element described in Patent Document 1, a light-emitting material is applied to interiors of plural cavities penetrating at least the dielectric layer and one of the electrode layers, and the light-emitting material is caused to emit light by applying a voltage to the cathode and anode. Accordingly, depending on the distribution state of the plural cavities that have been formed, uneven brightness on a light-emitting surface may occur in some cases.

An object of the present invention is to provide a method of manufacturing an organic electroluminescent element in which the uneven brightness is reduced on the light-emitting surface and uniform light emission is obtained.

### Solution to Problem

According to the present invention, there is provided a method of manufacturing an organic electroluminescent element including: a first organic electroluminescent element manufacture (first manufacturing process) of manufacturing the organic electroluminescent element in which at least a first electrode layer, a dielectric layer, and a second electrode layer are stacked on a substrate in this order, the organic electroluminescent element having a light-emitting portion that is in contact with an inner surface of a concave portion formed to penetrate the dielectric layer; a brightness distribution measurement process of measuring a brightness distribution of the organic electroluminescent element while causing the light-emitting portion to emit light by applying a voltage to the first electrode layer and the second electrode layer of the organic electroluminescent element manufactured in the first manufacturing process, and obtaining uneven brightness information of the organic electroluminescent element; and a second organic electroluminescent element manufacture (a second manufacturing process) of adjusting concave portion density on the basis of the uneven brightness information obtained in the brightness distribution measurement process, and reducing uneven brightness of the organic electroluminescent element.

Here, it is preferable that, in the brightness distribution measurement process, brightness of each part obtained by dividing a light-emitting surface of the organic electroluminescent element in light emission into predetermined sizes, a maximum brightness (L_{H}), and a minimum brightness (L_{L}) are measured as the uneven brightness information.

It is preferable that, in the brightness distribution measurement process, a ratio ((L_{H}−L_{L})/(L_{H}+L_{L})) of a difference (L_{H}−L_{L}) between the maximum brightness (L_{H}) and the minimum brightness (L_{L}) obtained by measuring the brightness distribution of the organic electroluminescent element in light emission to a sum (L_{H}+L_{L}) of the maximum brightness (L_{H}) and the minimum brightness (L_{L}) is obtained as the uneven brightness on the basis of the uneven brightness information.

It is preferable that, in the brightness distribution measurement process, a threshold is set at not more than 0.15, and the concave portion density is adjusted on the basis of the uneven brightness information in a case where the uneven brightness is larger than the threshold.

It is preferable that the concave portion penetrating at least any one of the first electrode layer and the second electrode layer is formed in the first manufacturing process and the second manufacturing process.

It is preferable that the concave portion penetrating the first electrode layer, the dielectric layer and the second electrode layer is formed in the first manufacturing process and the second manufacturing process.

### Advantageous Effects of Invention

According to the present invention, it is possible to reduce the uneven brightness on the light-emitting surface of the organic electroluminescent element and obtain uniform light emission.

### BRIEF DESCRIPTION OF DRAWINGS

FIG. 1 is a diagram for illustrating the first example of an organic electroluminescent element for the exemplary embodiment;

FIG. 2 is a diagram for illustrating the second example of the organic electroluminescent element for the exemplary embodiment;

FIG. 3 is a diagram for illustrating the third example of the organic electroluminescent element for the exemplary embodiment;

FIG. 4 is a diagram for illustrating the fourth example of the organic electroluminescent element for the exemplary embodiment;

FIG. 5 is a diagram for illustrating the fifth example of the organic electroluminescent element for the exemplary embodiment;

FIGS. 6A to 6F are diagrams for illustrating an example of the method of manufacturing the organic electroluminescent element to which the exemplary embodiment is applied;

FIG. 7 is a graph for illustrating relationship between the density of the concave portions and the brightness of the organic electroluminescent element in light emission;

FIG. 8 is a flowchart for illustrating the flow of the method of manufacturing the organic electroluminescent element to which the exemplary embodiment is applied;

FIG. 9 is a diagram for illustrating the light-emitting region of the organic electroluminescent element prepared in example 1;

FIGS. 10A to 10C are diagrams showing the measured results of the brightness distributions of the three organic electroluminescent elements prepared in example 1; and

FIGS. 11A and 11B are diagrams showing the measured results of the brightness distributions of the two organic electroluminescent elements prepared in example 2.

### DESCRIPTION OF EMBODIMENTS

Hereinafter, an exemplary embodiment of the present invention will be described in detail. Note that, the present invention is not limited to the exemplary embodiment given below, and it can be variously changed within the range of the gist. In other words, dimensions, materials, shapes, relative arrangement and the like of component parts described in examples of the exemplary embodiment are not to limit the scope of the present invention as long as particular description is not shown and are simply described as an example. In addition, drawings used here are examples for illustrating the exemplary embodiment, and actual size is not represented. Sizes, positional relations and the like of the components illustrated in each drawing may exaggerate for making the description clearer in some cases. Moreover, in the description, “on” included in “on a layer” or the like, is not limited to the case in which a material is formed to be in contact with an upper surface, and is used for cases including a case in which it is formed above with a gap and a case in which an interposed layer exists between layers.

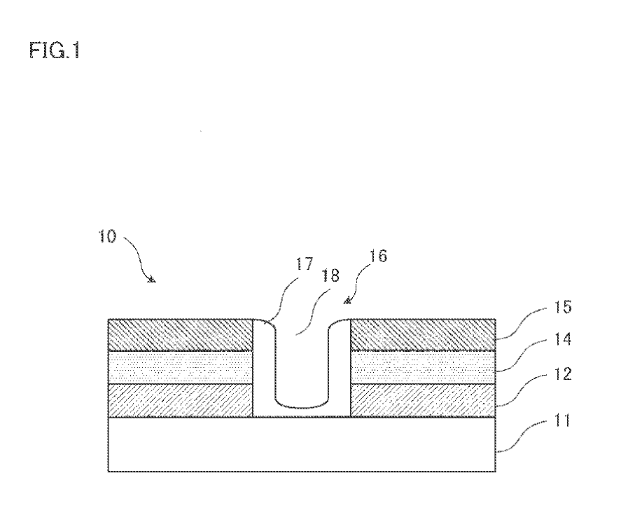

FIG. 1 is a diagram for illustrating the first example of an organic electroluminescent element for the exemplary embodiment.

An organic electroluminescent element 10 shown in FIG. 1 has a structure in which an anode layer 12 as a first electrode layer, a dielectric layer 14 that has an insulation property, and a cathode layer 15 as a second electrode layer are stacked on a substrate 11 in this order. Further, the organic electroluminescent element 10 has a concave portion 16 formed by penetrating the anode layer 12, the dielectric layer 14 and the cathode layer 15, and a light-emitting portion 17 that is formed to be in contact with the inner surface of the concave portion 16 and emits light with application of a voltage. The light-emitting portion 17 forms a second concave portion 18 by application of a light-emitting material to the inner surface of the concave portion 16 without entirely filling the concave portion 16 therewith.

Hereinbelow, each configuration will be explained.

### (Substrate 11)

The substrate 11 is a base material for forming the anode layer 12, the dielectric layer 14, the cathode layer 15, and the light-emitting portion 17. For the substrate 11, a material that satisfies mechanical strength required for the organic electroluminescent element 10 is used.

In the case where the light is desired to be extracted from the substrate 11 side of the organic electroluminescent element 10, the material for the substrate 11 needs to be transparent to the wavelength of light emitted from the light-emitting portion 17. Specific examples include: glasses such as soda glass, alkali-free glass and quartz glass; glass having a high refractive index; transparent resins such as acrylic resins, methacrylic resins, polycarbonate resins, polyester resins and nylon resins; oxides such as silicon oxide and aluminum oxide; nitrides such as silicon nitride, boron nitride, and aluminum nitride; fluorides such as magnesium fluoride and sodium fluoride; inorganic transparent materials other than the above; silicon; and the like.

In the case where it is unnecessary to extract the light from the substrate 11 side of the organic electroluminescent element 10, the material of the substrate 11 is not limited to the ones which are transparent to the wavelength of the light emitted from the light-emitting portion 17, and opaque materials can be used for the material. Specifically, for the material, in addition to the above-mentioned materials, metal single substances such as copper (Cu), silver (Ag), gold (Au), platinum (Pt), tungsten (W), titanium (Ti), tantalum (Ta), niobium (Nb) and the like; alloys thereof; materials composed of stainless steel or the like; opaque glasses; opaque resins; silicon; a semiconductor material such as gallium arsenide; composite materials such as fiber-reinforced plastic (FRP) can be used.

Although the thickness of the substrate 11 depends on the required mechanical strength, it is preferably 0.1 mm to 10 mm, and more preferably 0.25 mm to 2 mm.

### (Anode Layer 12)

A voltage is applied between the anode layer 12 serving as a first electrode layer and the cathode layer 15, and holes are injected to the light-emitting portion 17. A material used for the anode layer 12 is not particularly limited as long as it has electric conductivity. However, the surface resistance is preferably 1000Ω or less within a temperature range from −5° C. to 80° C., and is further preferably 100Ω or less. In addition, it is preferable that the electric resistance does not notably change for an alkaline aqueous solution. As the material satisfying such requirements, metal oxides, metals or alloys can be used. As the metal oxides, ITO (indium tin oxide) and IZO (indium zinc oxide) are provided, for example. As the metals, provided are: stainless steel; copper (Cu); silver (Ag); gold (Au); platinum (Pt); tungsten (W); titanium (Ti); tantalum (Ta); niobium (Nb) and the like. Further, alloys including these metals can be used.

The thickness of the anode layer 12 is preferably 2 nm to 300 nm since high light transmission is required in the case where the light is desired to be extracted from the substrate 11 side of the organic electroluminescent element 10. It can be formed to have the thickness of, for example, 2 nm to 2 mm in the case where it is not necessary to extract the light from the substrate 11 side of the organic electroluminescent element 10.

### (Dielectric Layer 14)

The dielectric layer 14 is provided between the anode layer 12 and the cathode layer 15, and is provided for applying a voltage to the light-emitting portion 17 in addition to separating the anode layer 12 and the cathode layer 15 with a predetermined interval and insulating them. Accordingly, the dielectric layer 14 needs to be a material having high resistivity, and is required to have the electric resistivity of not less than 10⁸ Ωcm, and preferably not less than 10¹² Ωcm.

Specific examples of the material include: metal nitrides such as silicon nitride, boron nitride and aluminum nitride; metal oxides such as silicon oxide and aluminum oxide; and fluorides such as magnesium fluoride and sodium fluoride. In addition, polymer compounds such as polyimide, polyvinylidene fluoride and parylene; inorganic transparent compounds other than the above, and porous substances thereof can be used. The thickness of the dielectric layer 14 is preferably not more than 1 μm in order to suppress the entire thickness of the organic electroluminescent element 10. In addition, since the voltage necessary to emit light is lower as the interval between the anode layer 12 and the cathode layer 15 is shorter, the dielectric layer 14 is preferably thin from this viewpoint. However, if it is too thin, dielectric strength possibly becomes insufficient for the voltage for driving the organic electroluminescent element 10. Here, as for the dielectric strength, current density of a current passing between the anode layer 12 and the cathode layer 15 in the state where the light-emitting portion 17 is not formed is preferably not more than 0.1 mA/cm², and more preferably not more than 0.01 mA/cm².

In addition, since the dielectric layer 14 preferably endures the voltage larger than the driving voltage of the organic electroluminescent element 10 by more than 2V, for example, in the case where the driving voltage is 5V, it is necessary to satisfy the aforementioned current density when the voltage of about 7V is applied between the anode layer 12 and the cathode layer 15 in the state where the light-emitting portion 17 is not formed. The thickness of the dielectric layer 14 that satisfies these requirements is formed to be preferably 10 nm to 500 nm, and further preferably 50 nm to 200 nm.

### (Cathode Layer 15)

The cathode layer 15 serving as a second electrode layer injects electrons into the light-emitting portion 17 upon application of a voltage between the anode layer 12 and the cathode layer 15. The material used for the cathode layer 15 is not particularly limited as long as, similarly to that of the anode layer 12, the material has electrical conductivity; however, it is preferable that the material has a low work function and is chemically stable. In view of the chemical stability, the work function is preferably not more than −2.9 eV. The specific examples of the material include: Al; MgAg alloy; alloys of Al and alkali metals such as AlLi and AlCa; and layers made of plural kinds of the materials included in the above. The thickness of the cathode layer 15 is preferably 10 nm to 1 μm, and more preferably 50 nm to 500 nm.

To lower the barrier for the electron injection from the cathode layer 15 into the light-emitting portion 17 and thereby to increase the electron injection efficiency, a cathode buffer layer that is not shown may be provided adjacent to the cathode layer 15. The cathode buffer layer needs to have a lower work function than the cathode layer 15, and metallic materials are preferably used therefor. For example, alkali metals (Na, K, Rb and Cs); alkaline earth metals (Sr, Ba, Ca and Mg); rare earth metals (Pr, Sm, Eu and Yb); one selected from fluoride, chloride and oxide of these metals and mixture of two or more selected therefrom can be used. The thickness of the cathode buffer layer is preferably 0.05 nm to 50 nm, more preferably 0.1 nm to 20 nm, and still more preferably 0.5 nm to 10 nm. In the case where such a cathode buffer layer is used, materials having a large absolute value of the work function which includes Au, Cu, Al, stainless steel, and transparent conductive oxides can be used for a third conductive layer.

### (Concave Portion (Cavity) 16)

The concave portion (cavity) 16 is provided for applying the light-emitting portion 17 to the inner surface thereof and extracting the light from the light-emitting portion 17, and is formed to penetrate the anode layer 12 serving as the first electrode layer, the cathode layer 15 serving as the second electrode layer and the dielectric layer 14. By providing the concave portion 16 as described above, the light emitted from the light-emitting portion 17 is transmitted to the inside of the concave portion 16, and the light can be extracted in both directions which are the substrate 11 side and the cathode layer 15 side. Here, since the concave portion 16 is formed to penetrate the anode layer 12, the dielectric layer 14 and the cathode layer 15, it is possible to extract the light even when the anode layer 12 serving as the first electrode layer and the cathode layer 15 serving as the second electrode layer are made of an opaque material.

Here, the shape of the concave portion 16 is not particularly limited. Although, in the exemplary embodiment, the concave portion 16 is formed into a cylinder-like shape as an example, it is not limited to this shape. In the case where the concave portion 16 is formed into a cylinder-like shape, the dimension thereof is preferably 0.1 μm to 20 μm, and more preferably 0.1 μm to 10 μm.

### (Light-Emitting Portion 17)

The light-emitting portion 17 is a light-emitting material that emits light by application of a voltage, and is applied to the inner surface of the concave portion 16 to form the second concave portion 18 by providing the light-emitting material to be in contact with the concave portion 16 as mentioned above. In the light-emitting portion 17, the holes injected from the anode layer 12 and the electrons injected from the cathode layer 15 are recombined, and light emission occurs.

As the material of the light-emitting portion 17, either low-molecular compound or high-molecular compound can be used. For example, light-emitting low-molecular compound and light-emitting high-molecular compound described in Oyo Butsuri (Applied Physics), Vol. 70, No. 12, pages 1419-1425 (2001) written by Yutaka Ohmori are exemplified. However, in the exemplary embodiment, a material having an excellent coating property is preferable. In other words, in the structure of the organic electroluminescent element 10, for stable light emission of the light-emitting portion 17 in the concave portion 16, it is preferable that the light-emitting portion 17 is uniformly in contact with the inner surface of the concave portion 16 and is formed to have a uniform thickness, that is, a coverage property thereof is improved.

Further, in order to form the light-emitting portion 17 uniformly in the concave portion 16, a coating method is preferably adopted. In other words, in the coating method, since it is easy to embed ink containing the light-emitting material into the concave portion 16, formation with high coverage property can be achieved even on a surface having asperity.

Specifically, examples of the material having an excellent coating property include: arylamine compound having a predetermined structure with a molecular weight of 1,500 or more to 6,000 or less disclosed in Japanese Patent Application Laid Open Publication No. 2007-86639; and a predetermined high molecular phosphor disclosed in Japanese Patent Application Laid Open Publication No. 2000-034476.

The light-emitting portion 17 of the organic electroluminescent element 10 according to the exemplary embodiment may include a hole-transporting compound or an electron-transporting compound in order to supplement the carrier transport property of the light-emitting portion 17.

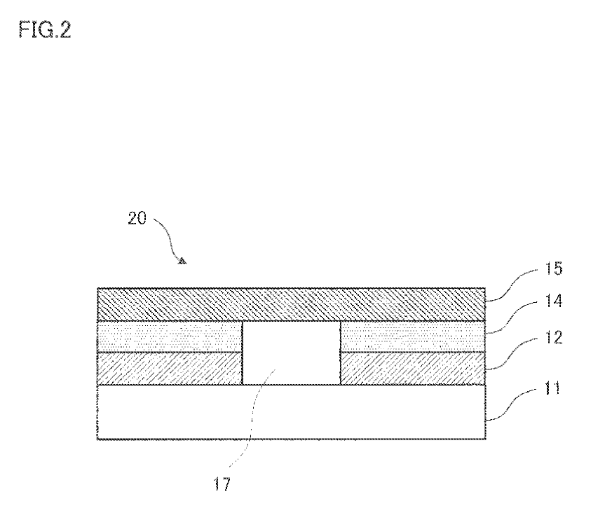

FIG. 2 is a diagram for illustrating the second example of the organic electroluminescent element for the exemplary embodiment.

In an organic electroluminescent element 20 shown in FIG. 2, although the concave portion 16 penetrates the anode layer 12 and the dielectric layer 14, it does not penetrate the cathode layer 15. In addition, the concave portion 16 is filled with the light-emitting portion 17, and the second concave portion 18 is not formed. Moreover, the cathode layer 15 is stacked on the dielectric layer 14, that is, the cathode layer 15 is formed like a so-called uniform film. Such a formation of the cathode layer 15 achieves the structure for covering the concave portion 16. Even though the light-emitting portion 17 is applied to the inner surface of the concave portion 16 not to form the second concave portion 18, the light emitted from the light-emitting portion 17 is transmitted to the inside of the light-emitting portion 17, and the light can be extracted in both directions which are the substrate 11 side and the cathode layer 15 side, similarly to the aforementioned organic electroluminescent element 10. However, in this organic electroluminescent element 20, since the cathode layer 15 as a uniform film covers the light-emitting portion 17, the light cannot be extracted from the cathode layer 15 side unless the cathode layer 15 is transparent to the wavelength of the light emitted from the light-emitting portion 17.

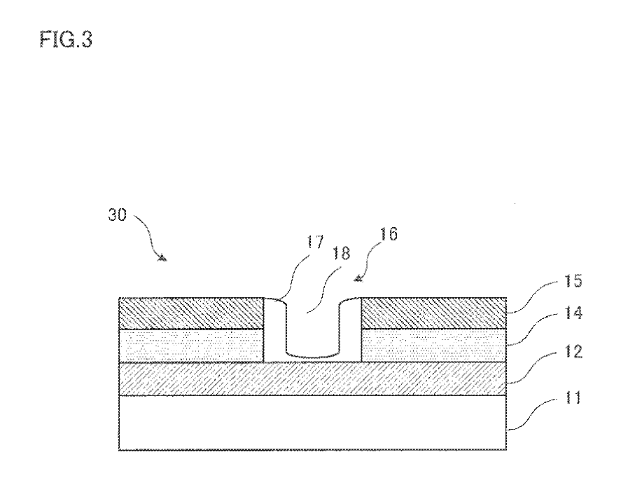

FIG. 3 is a diagram for illustrating the third example of the organic electroluminescent element for the exemplary embodiment.

In an organic electroluminescent element 30 shown in FIG. 3, although the concave portion 16 penetrates the dielectric layer 14 and the cathode layer 15, it does not penetrate the anode layer 12. In addition, the light-emitting portion 17 forms the second concave portion 18. Even in the case where the anode layer 12 is formed as mentioned above, the light emitted from the light-emitting portion 17 can be extracted in both directions which are the substrate 11 side and the cathode layer 15 side. However, in the case where the light is desired to be extracted from the anode layer 12 side, the light cannot be extracted from the substrate 11 side unless the anode layer 12 is transparent to the wavelength of the light emitted from the light-emitting portion 17.

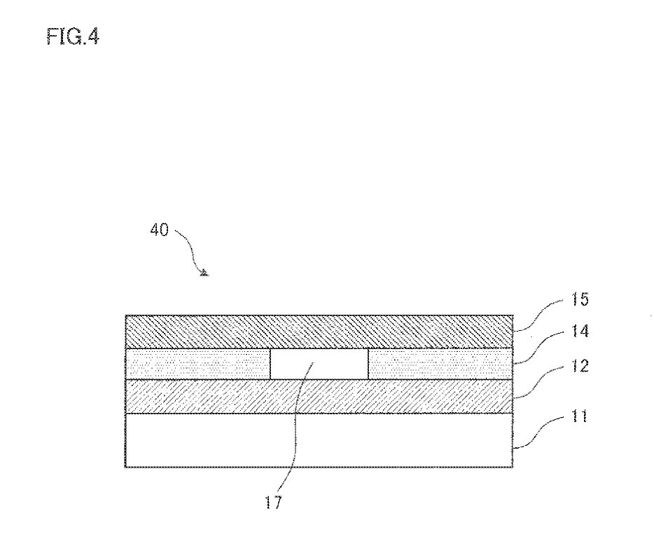

FIG. 4 is a diagram for illustrating the fourth example of the organic electroluminescent element for the exemplary embodiment.

In an organic electroluminescent element 40 shown in FIG. 4, although the concave portion 16 penetrates the dielectric layer 14, it does not penetrate the anode layer 12 and the cathode layer 15. In addition, the concave portion 16 is filled with the light-emitting portion 17, and the second concave portion 18 is not formed. Moreover, the anode layer 12 is stacked on the substrate 11, that is, the anode layer 12 is formed like a so-called uniform film. Further, the cathode layer 15 is stacked on the dielectric layer 14, that is, the cathode layer 15 is formed like a so-called uniform film, and the structure for covering the concave portion 16 is achieved. Even in the case where the anode layer 12 and the cathode layer 15 are formed as mentioned above, the light emitted from the light-emitting portion 17 can be extracted in both directions which are the substrate 11 side and the cathode layer 15 side. However, in the case where the light is desired to be extracted from the substrate 11 side, the anode layer 12 needs to be transparent to the wavelength of the light emitted from the light-emitting portion 17. Similarly, in the case where the light is desired to be extracted from the cathode layer 15 side, the cathode layer 15 needs to be transparent to the wavelength of the light emitted from the light-emitting portion 17.

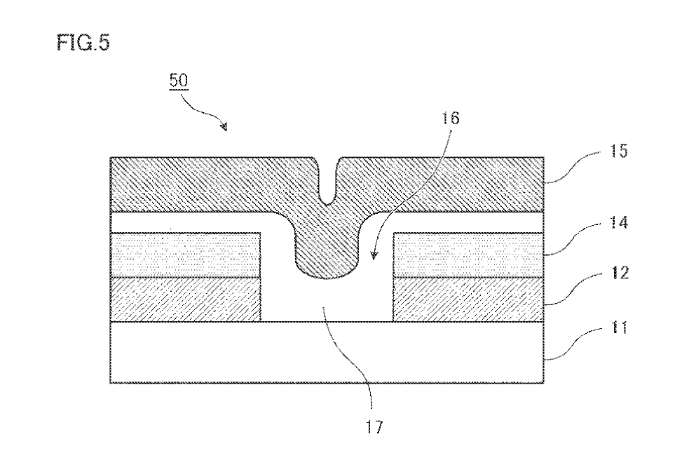

FIG. 5 is a diagram for illustrating the fifth example of the organic electroluminescent element for the exemplary embodiment.

In an organic electroluminescent element 50 shown in FIG. 5, the anode layer 12 and the dielectric layer 14 are formed on the substrate 11 in this order. The light-emitting material forming the light-emitting portion 17 is formed to further spread to the upper surface of the dielectric layer 14 from the concave portion 16. In other words, the light-emitting material forming the light-emitting portion 17 is further enlarged between the dielectric layer 14 and the cathode layer 15 from the concave portion 16, and is continuously formed. Moreover, the cathode layer 15 is formed to be further stacked on the light-emitting material, that is, it is formed like a so-called uniform film.

Note that, although in the organic electroluminescent elements 10, 20, 30, 40 and 50 which have been described above in detail, explanation has been done in a case where the anode layer 12 is formed on the lower side and the cathode layer 15 is formed on the upper side to face the anode layer 12 across the dielectric layer 14 on condition that the substrate 11 side is set to be the lower side, as an example, the structure is not limited to this, and the structure in which the anode layer 12 and the cathode layer 15 are reversed can be accepted. In other words, the configuration in which the cathode layer 15 is formed on the lower side and the anode layer 12 is formed on the upper side to face the cathode layer 15 across the dielectric layer 14 on condition that the substrate 11 side is set to be the lower side can be accepted.

### <Method of Manufacturing Organic Electroluminescent Element>

Next, the method of manufacturing the organic electroluminescent element will be explained, while the organic electroluminescent element 10 illustrated in FIG. 1 is taken as an example.

### (First Organic Electroluminescent Element Manufacture (Also Referred to as “First Manufacturing Process”)

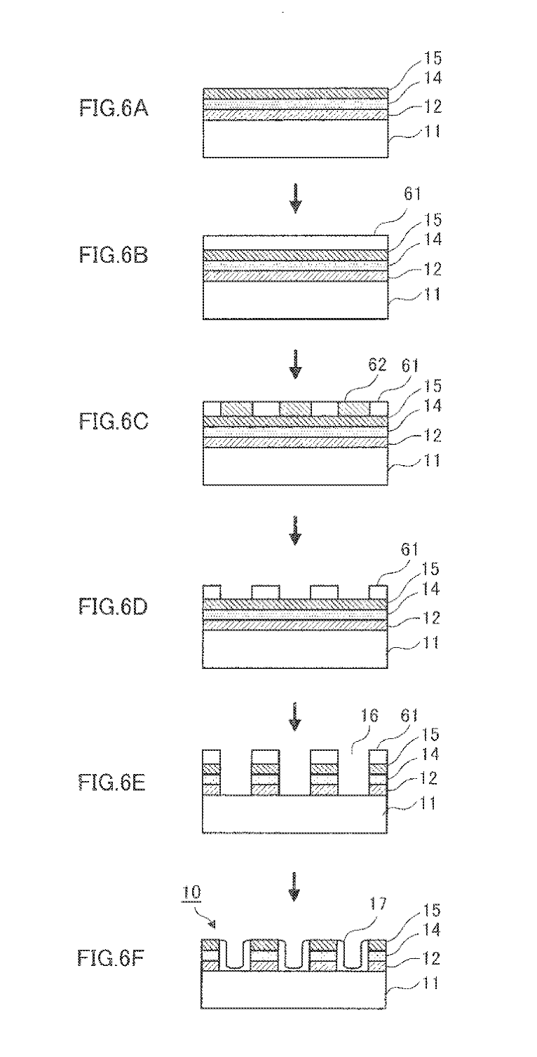

FIGS. 6A to 6F are diagrams for illustrating an example of the method of manufacturing the organic electroluminescent element 10 to which the exemplary embodiment is applied.

First, the anode layer 12, the dielectric layer 14 and the cathode layer 15 are formed to be stacked on the substrate 11 in this order (FIG. 6A). For forming these layers, a resistance heating deposition method, an electron beam deposition method, a sputtering method, an ion plating method, or the like can be used. Alternatively, if a coating film forming method (that is, a method for applying a material as a target solved in a solvent to the substrate and then drying the same) is applicable, they can be formed by a spin coating method, a dip coating method, an ink jet method, a printing method, a spray method, a dispenser method or the like. Note that, if the cathode buffer layer is desired to be provided, it can be formed by the similar method.

Next, the concave portion 16 is formed to penetrate the anode layer 12, the dielectric layer 14 and the cathode layer 15. For forming the concave portion 16, a method using photolithography can be used, for example. To form the concave portion 16, first, a photoresist solution is applied onto the cathode layer 15 and then an excess photoresist solution is removed by spin coating or the like to form a resist layer 61 (FIG. 6B).

Thereafter, the photoresist layer 61 is covered with a mask (not shown) in which a predetermined pattern for forming the concave portions 16 has been rendered, and is exposed with ultraviolet light (UV), an electron beam (EB) or the like. Here, if the exposure at the same magnification is performed (for example, in the case of contact exposure or proximity exposure), the pattern of the concave portions 16 at the same magnification of the mask pattern is formed. Alternatively, if reduction exposure is performed (in the case of the exposure using a stepper, for example), a pattern 62 of the concave portions 16 which is reduced with respect to the mask pattern is formed (FIG. 6C). Thereafter, upon removing unexposed portions of the photoresist layer 61 by use of a developing solution, the photoresist layer 61 at the pattern 62 is removed and a part of the cathode layer 15 is exposed (FIG. 6D).

Next, the exposed portions of the cathode layer 15 are removed by etching, and the concave portions 16 penetrating the anode layer 12, the dielectric layer 14 and the cathode layer 15 are formed (FIG. 6E). Either dry etching or wet etching can be used as the etching. Further, by combining isotropic etching and anisotropic etching at this time, the shape of the concave portion 16 can be controlled. Reactive ion etching (RIE) or inductive coupling plasma etching can be used as the dry etching, and a method of immersion in diluted hydrochloric acid, diluted sulfuric acid, or the like can be used as the wet etching.

Next, the residual photoresist layer 61 is removed by a photoresist removing solution or the like and the light-emitting portion 17 is formed, and thereby the organic electroluminescent element 10 is manufactured (FIG. 6F). For forming the light-emitting portion 17, the aforementioned coating method is used. First, application of ink in which the light-emitting material composing the light-emitting portion 17 is dispersed in a predetermined solvent such as an organic solvent, water or the like is performed. For the application, various kinds of methods such as a spin coating method, a spray coating method, a dip coating method, an ink jet method, a slit coating method, a dispenser method, and a printing method can be used. After the application, the ink is dried by heat or vacuuming, the light-emitting material adheres to the inner surface of the concave portion 16, and the light-emitting portion 17 is formed.

### (Brightness Distribution Measurement Process)

Subsequently, the organic electroluminescent element 10 manufactured in the first manufacturing process is caused to emit light, and the brightness distribution is measured. Specifically, a voltage is applied to the organic electroluminescent element 10 from a direct-current power source so that the average of the current density becomes, for example, 1 mA/cm², the organic electroluminescent element 10 is caused to drive and to turn on light with a predetermined average of the brightness, and the brightness distribution is measured by use of a predetermined luminance meter. As the number of samples of the organic electroluminescent element 10 for measuring the brightness distribution increases, the brightness distribution can be precisely measured. In the exemplary embodiment, not less than 10 samples are preferable, and it is more preferable that all samples are measured.

In the case of measuring the brightness distribution, a light-emitting surface of the element sample to be measured is divided into, for example, a grid or a honeycomb, and the brightness of each part is measured. It is preferable that the surface is divided into square grids so that they are easy in handling. The divided number of the light-emitting surface is not particularly limited. However, in the case where the number of the element samples to be measured is not less than 10, it is preferably divided so that one region has an area of approximately 0.1 mm² to 10 cm². In the case where all samples are measured, it is preferably divided so that one region has an area of approximately 1 mm² to 1 cm². In this way, the brightness of each divided part is measured, and further, average brightness of the samples is obtained.

By the measurement of the brightness distribution, the maximum brightness (L_{H}) and the minimum brightness (L_{L}) of the organic electroluminescent element 10 in light emission are obtained as uneven brightness information.

Next, on the basis of the uneven brightness information obtained by the measurement of the brightness distribution, uneven brightness of the organic electroluminescent element 10 in light emission is calculated by a following calculating formula (1).

Uneven brightness=(L_{H}−L_{L})/(L_{H}+L_{L}) (1)

Subsequently, in the case where the uneven brightness calculated by the calculating formula (1) is larger than a predetermined threshold, the organic electroluminescent element 10 is manufactured again in a subsequent manufacture (the second manufacturing process) while the density of the concave portions 16 is adjusted on the basis of the uneven brightness information of the organic electroluminescent element 10 manufactured in the first manufacturing process. Note that, for making the uneven brightness unnoticed with the naked eye under a general lighting, the aforementioned threshold is preferably 0.1 or less, and more preferably 0.05 or less. Further, for the usage that is sensitive to the uneven brightness (for example, some lighting with priority on the design), the aforementioned threshold can be set at 0.05 or less, and further at 0.02 or less in the present invention.

### (Second Organic Electroluminescent Element Manufacture (Also Referred to as “Second Manufacturing Process”)

In the second manufacturing process, similarly to the first manufacturing process that has been mentioned, the anode layer 12, the dielectric layer 14 and the cathode layer 15 are stacked on the substrate 11 in this order, and then the plural concave portions 16 penetrating the anode layer 12, the dielectric layer 14 and the cathode layer 15 are formed by photolithography.

In the second manufacturing process, the density of the concave portions 16 is adjusted on the basis of the uneven brightness information of the organic electroluminescent element 10 manufactured in the first manufacturing process.

A partial brightness of the organic electroluminescent element 10 in light emission is easily influenced by the density rather than the size and the shape of the concave portion 16, and the density of the plural concave portions 16 is preferably controlled for controlling the brightness distribution.

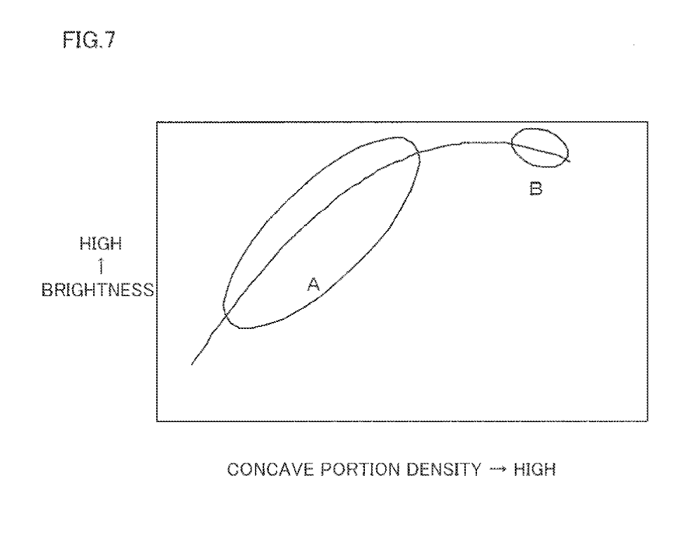

FIG. 7 is a graph for illustrating relationship between the density of the concave portions 16 and the brightness of the organic electroluminescent element 10 in light emission.

In FIG. 7, a region A shows a region in which the partial brightness of the organic electroluminescent element 10 increases as the density of the concave portions 16 increases. Moreover, a region B shows a region in which the partial brightness of the organic electroluminescent element 10 decreases as the density of the concave portions 16 increases. The condition of the region A or the region B can be obtained by measurement of the relationship between the density of the concave portions 16 and the brightness in a preliminary experiment in advance.

In order to adjust the density of the concave portions 16 so that the brightness distribution becomes uniform, for example, in the region A, operation in which the density of the concave portions 16 at a high brightness part is decreased and the density of the concave portions 16 at a low brightness part is increased is performed when the concave portions 16 are formed on the basis of the measurement values of the brightness as the uneven brightness information of the organic electroluminescent element 10 manufactured in the first manufacturing process.

Similarly, in the region B, operation in which the density of the concave portions 16 at the high brightness part is increased and the density of the concave portions 16 at the low brightness part is decreased is performed when the concave portions 16 are formed.

Specifically, for example, at the exposure of the photoresist layer, exposure is performed while the density of the concave portions 16 is adjusted by changing the scale of the mask for each predetermined part with a stepper exposure apparatus.

As for the range of changing the density of the concave portions 16, in general, it is preferable that the density changes within a range equivalent to the rate of a difference in brightness at a particular part with respect to the average brightness of the entire organic electroluminescent element 10 to a range of about one-tenth of that range (hereinbelow, referred to as “feedback rate 1 to 1/10”), in a range in which the uneven brightness obtained by the calculating formula (1) doe not diverge but converges. For example, in the region A in FIG. 7, in the case where the brightness at a certain part is higher than the average brightness by 10%, the density of the concave portions 16 at the part is preferably decreased with a step of 1% to 10%. By adjusting the density of the concave portions 16 with such a range, the uneven brightness of the organic electroluminescent element 10 is averaged.

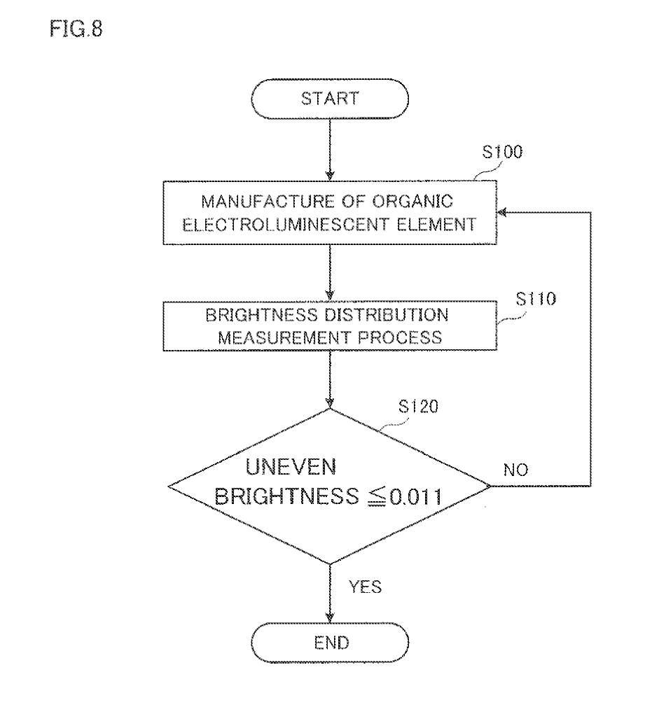

FIG. 8 is a flowchart for illustrating the flow of the method of manufacturing the organic electroluminescent element 10 to which the exemplary embodiment is applied.

In the method of manufacturing the organic electroluminescent element 10, as the first manufacturing process, the organic electroluminescent element 10 having a structure in which the anode layer 12, the dielectric layer 14 and the cathode layer 15 are stacked on the substrate 11 in this order, and having the light-emitting portion 17 formed to be in contact with the inner surface of the concave portion 16 penetrating those layers is manufactured (step 100).

Subsequently, as the brightness distribution measurement process, the organic electroluminescent element 10 manufactured in the first manufacturing process is caused to emit light, the brightness distribution of the organic electroluminescent element 10 is measured, and the uneven brightness information is obtained (step 110). The uneven brightness information includes the measured brightness of each part obtained by dividing the light-emitting surface of the organic electroluminescent element 10 into predetermined sizes, the maximum brightness (L_{H}) and the minimum brightness (L_{L}). Then, on the basis of the obtained uneven brightness information, the uneven brightness of the organic electroluminescent element 10 in light emission is calculated by the aforementioned calculating formula (1).

Next, whether the uneven brightness calculated in the brightness distribution measurement process is higher than the predetermined threshold (in the exemplary embodiment, explanation will be given on condition that it is set at 0.011) or not is determined (step 120). In the case where the uneven brightness is higher than the threshold (0.011) (NO), the uneven brightness information is fed back to the first manufacturing process, and the organic electroluminescent element 10 is manufactured while the density of the concave portions 16 is adjusted (the second manufacturing process).

Again, in the brightness distribution measurement process, the brightness distribution of the organic electroluminescent element 10 manufactured in the second manufacturing process is measured, whether the obtained uneven brightness is higher than the threshold (0.011) or not is determined, the uneven brightness information is fed back to the first manufacturing process in the case where it is higher than the threshold, and the process for adjusting the density of the concave portions 16 is repeated until the uneven brightness becomes the threshold (0.011) or below.

By the above processes, the organic electroluminescent element 10 can be manufactured. Note that, in the case where the organic electroluminescent element 10 is used in a stable manner for long period, a protective layer or a protective cover (not shown) for protecting the organic electroluminescent element 10 from the outside is preferably mounted thereon. As the protective layer, high-molecular compounds, metal oxides, metal fluorides, metal borides, silicon compounds such as silicon nitride and silicon oxide, or the like can be used. In addition, the stacked layers thereof can be used. As the protective cover, a glass plate, a plastic plate whose surface has been treated to have low hydraulic permeability, metals or the like can be used.

### EXAMPLES

Hereinafter, the present invention will be further explained in detail on the basis of examples. However, the present invention is not limited to the following examples.

### Example 1

In accordance with the following operation, a first organic electroluminescent element (an organic electroluminescent element 1) having the plural concave portions (cavities) 16 formed into a uniform pattern was firstly manufactured and was caused to emit light, and the brightness distribution was measured (measurement value 1). Next, a second organic electroluminescent element (an organic electroluminescent element 2) was manufactured while the density of the concave portions 16 at the high brightness part in the light-emitting surface was adjusted to be decreased and the density of the concave portions 16 at the low brightness part was adjusted to be increased on the basis of the measurement value 1, and was caused to emit light, and the brightness distribution was measured (measurement value 2). Further, a third organic electroluminescent element (an organic electroluminescent element 3) was manufactured while the density of the concave portions 16 at the high brightness part in the light-emitting surface was adjusted to be decreased and the density of the concave portions 16 at the low brightness part was adjusted to be increased on the basis of the measurement value 2, and was caused to emit light, and the brightness distribution was measured (measurement value 3).

### (Preparation of Light-Emitting Material Solution (Ink)-1)

In accordance with the method described in the international publication brochure WO2010-16512, paragraph [0077] on page 24 to paragraph [0078] on page 25, a light-emitting high-molecular compound (A) having a phosphorescent property which would be shown below was synthesized. The weight-average molecular weight of the light-emitting high-molecular compound (A) is 52,000, and the mole ratio of each repeating unit is k:m:n=6:42:52.

A light-emitting material solution (hereinafter, also referred to as “solution A”) was prepared by dissolving 3 parts by weight of the light-emitting high-molecular compound (A) in 97 parts by weight of toluene.

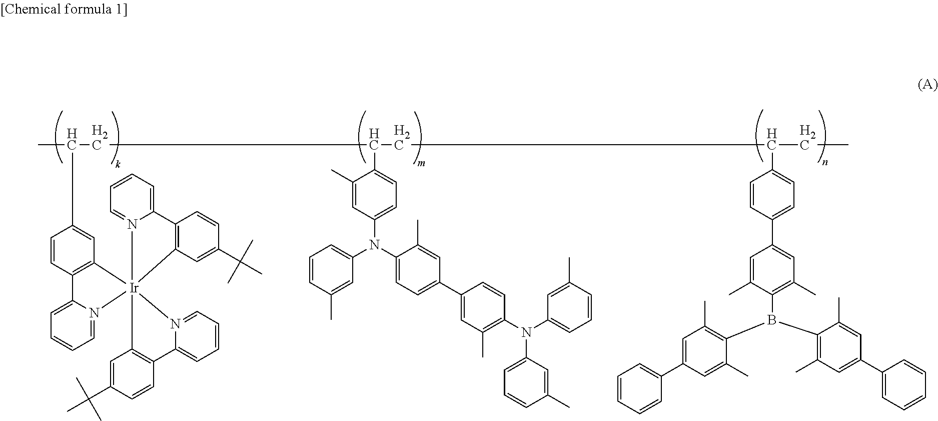

### (Preparation of Organic Electroluminescent Element 1)

In accordance with the following operation, the organic electroluminescent element 1 having a layer structure of the organic electroluminescent element 50 in FIG. 5 was prepared.

A glass substrate (310 mm per side, thickness of 1 mm) on which an ITO film of 300 nm in thickness having a patterning corresponding to a light-emitting region having 300 mm per side had been formed was ultrasonically cleaned with surfactant, with pure water and with isopropanol in this order. The cleaned glass substrate with ITO was placed in a plasma generator, and was irradiated with oxygen plasma for 5 seconds under a condition that the pressure in the generator was set at 1 Pa and the input power was set at 50 W. Next, the glass substrate with ITO was placed in a sputtering apparatus, and a SiO₂ layer having the thickness of 50 nm was formed on the whole surface of the light-emitting region by sputtering.

Here, the glass substrate is the substrate 11, ITO is the first electrode layer (anode layer) 12, and the SiO₂ layer is the dielectric layer 14.

Next, a photoresist (AZ1500 manufactured by AZ Electronic Materials) layer of about 1 μm in thickness was formed on the whole surface of the glass substrate on which ITO and the SiO₂ layer had been formed, by a spin coating method. Subsequently, a mask A corresponding to the pattern in which circles were arranged to form a hexagonal lattice was prepared with quartz (thickness of 3 mm) as a base material, and a region of 10 mm square at a corner of the light-emitting region was exposed with a quarter scale by use of a stepper exposure apparatus. Next, another region of 10 mm square adjacent to the exposed region was similarly exposed, and the entire region of 300 mm square was exposed by repeating this operation. Subsequently, after development was executed with 1.2% solution of tetramethyl ammonium hydroxide (TMAH: (CH₃)₄NOH) and thereby the photoresist layer was patterned, heat was applied for 10 minutes at 130° C.

Next, dry etching processing was performed with a reactive ion etching device by using CHF₃ as a reactant gas for 10 minutes under a condition that the pressure was 0.3 Pa and output bias/ICP=50/100 (W). Then, the residue of the photoresist was removed by a photoresist removing solution and an electrode substrate in which the plural concave portions (cavities) 16 penetrating the SiO₂ layer and the ITO layer had been formed was obtained. The concave portions (cavities) 16 each had a cylinder shape with a diameter of 1 μm, and they were formed to be arrayed in a hexagonal lattice pattern with a pitch of 2 μm on the whole area of the SiO₂ layer and the ITO layer.

Subsequently, the solution A was applied, by the spin coating method (spin rate: 3000 rpm), onto the electrode substrate on which the aforementioned plural concave portions (cavities) 16 had been formed, the resultant substrate was left and dried under a nitrogen atmosphere at the temperature of 140° C. for an hour, and the light-emitting portion 17 was formed.

Next, a sodium fluoride layer (4 nm) as the cathode buffer layer and an aluminum layer (130 nm) as the cathode layer 15 were formed in this order on the aforementioned light-emitting portion 17 by a vapor-deposition method, and the organic electroluminescent element 1 was prepared.

Note that, the organic electroluminescent element 1 thus obtained was an element having a property included in the aforementioned region A.

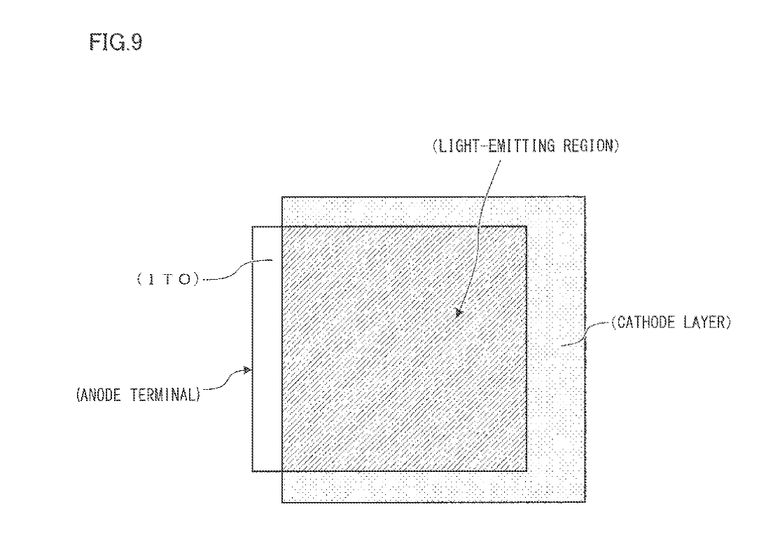

FIG. 9 is a diagram for illustrating the light-emitting region of the organic electroluminescent element 1. As shown in FIG. 9, when the organic electroluminescent element 1 is planarly viewed from the cathode layer 15 side, the section where the ITO as the anode layer and the aluminum layer as the cathode layer are overlapped with each other becomes the light-emitting region. Note that, an anode terminal has been formed at one end of ITO.

A voltage was applied to the organic electroluminescent element 1 thus prepared, and the organic electroluminescent element 1 was driven so that the average of the current density in the light-emitting surface became 1 mA/cm².

Upon measuring the brightness distribution in the light-emitting surface of the organic electroluminescent element 1 by use of the luminance meter, the brightness at the region near the anode terminal in the light-emitting surface was the highest, and it was 250 cd/m². The brightness in the light-emitting surface decreased as the distance from the anode terminal increased, and the brightness at the region farthest from the anode terminal was 200 cd/m².

Here, in the organic electroluminescent element 1 in light emission, the uneven brightness in the light-emitting surface calculated by the aforementioned formula (1) (uneven brightness=(maximum brightness−minimum brightness)/(maximum brightness+minimum brightness)) was about 0.11 (11%).

### (Preparation of Organic Electroluminescent Element 2)

Next, by operation similar to the preparation of the organic electroluminescent element 1, after the SiO₂ layer was formed on the glass substrate with ITO, the photoresist layer was formed thereon. By using the mask A same as that in the case of the organic electroluminescent element 1, a region of 1 cm square was repeatedly exposed by operation similar to the one for preparing the organic electroluminescent element 1 except changing the scale of the exposure by use of the stepper exposure apparatus as mentioned below, and the whole surface of the light-emitting region was exposed.

That is, for exposing the photoresist layer, the light-emitting region was equally divided into 10 sections from a side near the anode terminal to a side far therefrom, and the scale of the exposure pattern was changed for the respective sections. The scale at the region nearest to the anode terminal where the maximum brightness had been measured in the organic electroluminescent element 1 was set at 50/200 that was the same scale as the case of the organic electroluminescent element 1. At the region farthest from the anode terminal where the minimum brightness had been measured in the organic electroluminescent element 1, the scale was set at 41/200. At the exposure, the scale was changed by 1/200 at a time in stages.

Thereafter, by operation similar to the one for preparing the organic electroluminescent element 1, patterning of the photoresist layer, formation of the plural concave portions (cavities) 16 with dry etching, and formation of the light-emitting portion 17, the cathode buffer layer and the cathode layer 15 were achieved, and thereby the organic electroluminescent element 2 was prepared.

A voltage was applied to the organic electroluminescent element 2 thus prepared, and the organic electroluminescent element 2 was driven so that the average of the current density in the light-emitting surface became 1 mA/cm².

Upon measuring the brightness distribution in the light-emitting surface by use of the luminance meter, the maximum brightness observed in the light-emitting surface was 235 cd/m², and the minimum brightness was 220 cd/m². The uneven brightness in the light-emitting surface calculated by the aforementioned formula (1) (uneven brightness=(maximum brightness−minimum brightness)/(maximum brightness+minimum brightness)) was decreased to about 0.033 (3.3%).

### (Preparation of Organic Electroluminescent Element 3)

Subsequently, by using the mask A same as that in the case of the organic electroluminescent element 1, the organic electroluminescent element 3 was prepared by operation similar to the one for preparing the organic electroluminescent element 1 except the scale at exposing the photoresist layer was changed as mentioned below.

That is, the scale of the exposure was increased by 1/200 for the light-emitting region of 1 cm square which included the measured part where the observed brightness had been in the range from 230 cd/m² to 235 cd/m² in the organic electroluminescent element 2. Meanwhile, the scale of the exposure was decreased by 1/200 for the light-emitting region of 1 cm square which included the measured part where the brightness had been in the range from 220 cd/m² to 225 cd/m².

A voltage was applied to the prepared organic electroluminescent element 3, and the organic electroluminescent element 3 was driven so that the average of the current density in the light-emitting surface became 1 mA/cm².

Upon measuring the brightness distribution in the light-emitting surface by use of the luminance meter, the maximum brightness observed in the light-emitting surface was 230 cd/m², and the minimum brightness was 225 cd/m². The uneven brightness in the light-emitting surface calculated by the aforementioned formula (1) (uneven brightness=(maximum brightness−minimum brightness)/(maximum brightness+minimum brightness)) was decreased to about 0.011 (1.1%).

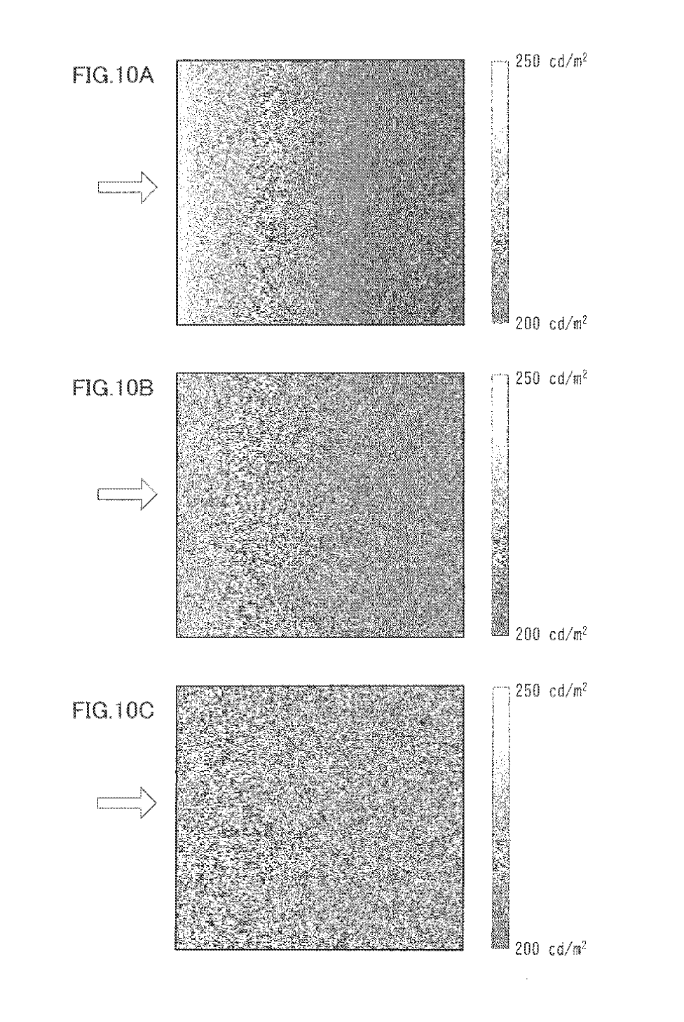

FIGS. 10A to 10C are diagrams showing the measured results of the brightness distributions of the three organic electroluminescent elements prepared in example 1. FIG. 10A is a measured result of the brightness distribution of the organic electroluminescent element 1, FIG. 10B is a measured result of the brightness distribution of the organic electroluminescent element 2, and FIG. 10C is a measured result of the brightness distribution of the organic electroluminescent element 3. Note that, an arrow denotes the anode terminal side.

### Example 2

An organic electroluminescent element 4 and an organic electroluminescent element 5 were prepared by operation similar to the one in Example 1, while a kind of the light-emitting material solution forming the light-emitting portion 17 was changed.

### (Preparation of Light-Emitting Material Solution (Ink)-2)

A solution B was prepared by operation similar to the one for preparing the solution A except changing the solvent used for the aforementioned preparation of the solution A into xylene.

### (Preparation of Organic Electroluminescent Element 4)

The organic electroluminescent element 4 was prepared with the solution B by operation similar to the organic electroluminescent element 1 except setting the scale of the exposure at each region of 1 cm square in the light-emitting regions at the same value as the case of the organic electroluminescent element 3.

A voltage was applied to the prepared organic electroluminescent element 4, and the organic electroluminescent element 4 was driven so that the average of the current density in the light-emitting surface became 1 mA/cm².

Upon measuring the brightness distribution in the light-emitting surface by use of the luminance meter, the maximum brightness observed in the light-emitting surface is 245 cd/m², and the minimum brightness is 230 cd/m². The uneven brightness in the light-emitting surface calculated by the aforementioned formula (1) (uneven brightness=(maximum brightness−minimum brightness)/(maximum brightness+minimum brightness)) was about 0.031 (3.2%).

### (Preparation of Organic Electroluminescent Element 5)

The electroluminescent element 5 was prepared by operation similar to the one for preparing the organic electroluminescent element 4 except the scale at exposing the photoresist layer was changed as mentioned below, by using the mask A for preparing the aforementioned organic electroluminescent element 4.

That is, the scale of the exposure was increased by 1/200 for the light-emitting region of 1 cm square which included the measured part where the observed brightness had been in the range from 240 cd/m² to 245 cd/m² in the organic electroluminescent element 4. In a similar manner, the scale of the exposure was decreased by 1/200 for the light-emitting region of 1 cm square which included the measured part where the brightness had been in the range from 230 cd/m² to 235 cd/m².

A voltage was applied to the prepared organic electroluminescent element 5, and the organic electroluminescent element 5 was driven so that the average of the current density in the light-emitting surface became 1 mA/cm².

Upon measuring the brightness distribution in the light-emitting surface by use of the luminance meter, the maximum brightness observed in the light-emitting surface is 240 cd/m², and the minimum brightness is 235 cd/m². The uneven brightness in the light-emitting surface calculated by the aforementioned formula (1) (uneven brightness=(maximum brightness−minimum brightness)/(maximum brightness+minimum brightness)) was decreased to about 0.011 (1.1%).

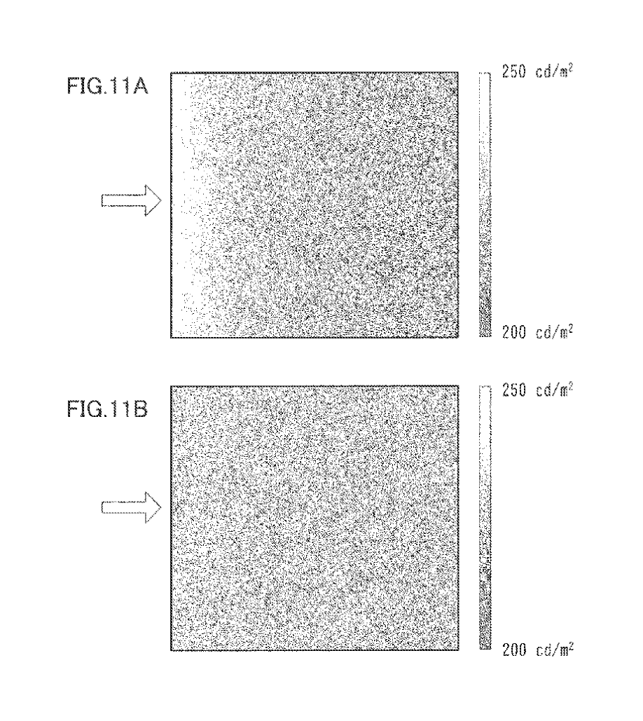

FIGS. 11A and 11B are diagrams showing the measured results of the brightness distributions of the two organic electroluminescent elements prepared in example 2. FIG. 11A is a measured result of the brightness distribution of the organic electroluminescent element 4, and FIG. 11B is a measured result of the brightness distribution of the organic electroluminescent element 5. Note that, an arrow denotes the anode terminal side.

### REFERENCE SIGNS LIST

10, 20, 30, 40, 50 . . . Organic electroluminescent element
11 . . . Substrate
12 . . . Anode layer
14 . . . Dielectric layer
15 . . . Cathode layer
16 . . . Concave portion
17 . . . Light-emitting portion
18 . . . Second concave portion

1. A method of manufacturing an organic electroluminescent element comprising:
a first organic electroluminescent element manufacture (first manufacturing process) of manufacturing the organic electroluminescent element in which at least a first electrode layer, a dielectric layer, and a second electrode layer are stacked on a substrate in this order, the organic electroluminescent element having a light-emitting portion that is in contact with an inner surface of a concave portion formed to penetrate the dielectric layer;
a brightness distribution measurement process of measuring a brightness distribution of the organic electroluminescent element while causing the light-emitting portion to emit light by applying a voltage to the first electrode layer and the second electrode layer of the organic electroluminescent element manufactured in the first manufacturing process, and obtaining uneven brightness information of the organic electroluminescent element; and
a second organic electroluminescent element manufacture (a second manufacturing process) of adjusting concave portion density on the basis of the uneven brightness information obtained in the brightness distribution measurement process, and reducing uneven brightness of the organic electroluminescent element.

2. The method of manufacturing the organic electroluminescent element according to claim 1, wherein
in the brightness distribution measurement process, brightness of each part obtained by dividing a light-emitting surface of the organic electroluminescent element in light emission into predetermined sizes, a maximum brightness (L_{H}), and a minimum brightness (L_{L}) are measured as the uneven brightness information.

3. The method of manufacturing the organic electroluminescent element according to claim 1, wherein
in the brightness distribution measurement process, a ratio ((L_{H}−L_{L})/(L_{H}+L_{L})) of a difference (L_{H}−L_{L}) between the maximum brightness (L_{H}) and the minimum brightness (L_{L}) obtained by measuring the brightness distribution of the organic electroluminescent element in light emission to a sum (L_{H}+L_{L}) of the maximum brightness (L_{H}) and the minimum brightness (L_{L}) is obtained as the uneven brightness on the basis of the uneven brightness information.

4. The method of manufacturing the organic electroluminescent element according to claim 3, wherein
in the brightness distribution measurement process, a threshold is set at not more than 0.15, and the concave portion density is adjusted on the basis of the uneven brightness information in a case where the uneven brightness is larger than the threshold.

5. The method of manufacturing the organic electroluminescent element according to claim 1, wherein
the concave portion penetrating at least any one of the first electrode layer and the second electrode layer is formed in the first manufacturing process and the second manufacturing process.

6. The method of manufacturing the organic electroluminescent element according to claim 1, wherein
the concave portion penetrating the first electrode layer, the dielectric layer and the second electrode layer is formed in the first manufacturing process and the second manufacturing process.
